(19) United States
(12) Patent Application Publication
(10) Pub. No.: US 2008/0145191 A1
(43) Pub. Date: Jun. 19, 2008

(54) ACTIVELY CHILLED SUBSTRATE TRANSPORT MODULE

(75) Inventors: Martin Jeff Salinas, San Jose, CA (US); Tetsuya Ishikawa, Saratoga, CA (US); David H. Quach, San Jose, CA (US); Natarajan Ramanan, San Jose, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SOKUDO CO., LTD., Kyoto (JP)

(21) Appl. No.: 11/689,372

(22) Filed: Mar. 21, 2007

Related U.S. Application Data
(60) Provisional application No. 60/866,039, filed on Nov. 15, 2006.

(51) Int. Cl. H01L 21/677

(52) U.S. Cl. 414/217; 414/805

(57) ABSTRACT

A substrate transport module adapted to transport a substrate in a processing chamber of a semiconductor processing apparatus. The substrate transport module includes a substrate cooling surface and a plurality of coolant channels disposed in the substrate transport module and in thermal communication with the substrate cooling surface. The substrate transport module also includes a plurality of vacuum channels disposed in the substrate transport module and a plurality of proximity pins extending to a predetermined height above the substrate cooling surface. Each of the plurality of proximity pins is in fluid communication with one or more of the plurality of vacuum channels.

This application claims benefit under 35 U.S.C. § 119(e) of U.S. Provisional Patent Application No. 60/866,039, filed Nov. 15, 2006, the disclosure of which is hereby incorporated by reference in its entirety for all purposes.

### BACKGROUND OF THE INVENTION

The present invention relates generally to the field of substrate processing equipment. More particularly, the present invention relates to a method and apparatus for transporting semiconductor substrates in an integrated bake unit of a track lithography tool. Merely by way of example, the method and apparatus of the present invention are used to transport a semiconductor wafer with an actively chilled wafer transport module. The method and apparatus can be applied to other processes for semiconductor substrates including other processing chambers.

Modern integrated circuits contain millions of individual elements that are formed by patterning the materials, such as silicon, metal and dielectric layers, that make up the integrated circuit to sizes that are small fractions of a micrometer. The technique used throughout the industry for forming such patterns is photolithography. A typical photolithography process sequence generally includes depositing one or more uniform photoresist (resist) layers on the surface of a substrate, drying and curing the deposited layers, patterning the substrate by exposing the photoresist layer to radiation that is suitable for modifying the exposed layer and then developing the patterned photoresist layer.

It is common in the semiconductor industry for many of the steps associated with the photolithography process to be performed in a multi-chamber processing system (e.g., a cluster tool) that has the capability to sequentially process semiconductor wafers in a controlled manner. One example of a cluster tool that is used to deposit (i.e., coat) and develop a photoresist material is commonly referred to as a track lithography tool.

Track lithography tools typically include a mainframe that houses multiple chambers (which are sometimes referred to herein as stations) dedicated to performing the various tasks associated with pre- and post-lithography processing. There are typically both wet and dry processing chambers within track lithography tools. Wet chambers include coat and/or develop bowls, while dry chambers include thermal control units that house bake and/or chill plates. Track lithography tools also frequently include one or more pod/cassette mounting devices, such as an industry standard FOUP (front opening unified pod), to receive substrates from and return substrates to the clean room, multiple substrate transfer robots to transfer substrates between the various stations of the track tool and an interface that allows the tool to be operatively coupled to a lithography exposure tool in order to transfer substrates into the exposure tool and to receive substrates after they have been processed within the exposure tool.

Over the years there has been a strong push within the semiconductor industry to shrink the size of semiconductor devices. The reduced feature sizes have caused the industry's tolerance to process variability to shrink, which in turn, has resulted in semiconductor manufacturing specifications having more stringent requirements for process uniformity and repeatability. An important factor in minimizing process variability during track lithography processing sequences is to ensure that every substrate processed within the track lithography tool for a particular application has the same “wafer history.” A substrate's wafer history is generally monitored and controlled by process engineers to ensure that all of the device fabrication processing variables that may later affect a device's performance are controlled, so that all substrates in the same batch are always processed the same way.

To ensure that each substrate has the same “wafer history” requires that each substrate experiences the same repeatable substrate processing steps (e.g., consistent coating process, consistent hard bake process, consistent chill process, etc.) and the timing between the various processing steps is the same for each substrate. Lithography type device fabrication processes can be especially sensitive to variations in process recipe variables and the timing between the recipe steps, which directly affects process variability and ultimately device performance.

In view of these requirements, the semiconductor industry is continuously researching methods and developing tools and techniques that can improve the uniformity in wafer history for track lithography and other types of cluster tools.

### SUMMARY OF THE INVENTION

According to the present invention, techniques related to the field of semiconductor processing equipment are provided. More particularly, the present invention relates to a method and apparatus for transporting semiconductor substrates in an integrated bake unit of a track lithography tool. Merely by way of example, the method and apparatus of the present invention are used to transport a semiconductor wafer with an actively chilled wafer transport module. The method and apparatus can be applied to other processes for semiconductor substrates including other processing chambers.

According to an embodiment of the present invention, a substrate transport module adapted to transport a substrate in a processing chamber of a semiconductor processing apparatus is provided. The substrate transport module includes a substrate cooling surface and a plurality of coolant channels disposed in the substrate transport module and in thermal communication with the substrate cooling surface. The substrate transport module also includes a plurality of vacuum channels disposed in the substrate transport module and a plurality of proximity pins extending to a predetermined height above the substrate cooling surface. Each of the plurality of proximity pins is in fluid communication with one or more of the plurality of vacuum channels.

According to another embodiment of the present invention, a method of transporting a substrate from a first location in a processing chamber of a semiconductor processing apparatus to a second location in the processing chamber is provided. The method includes moving a substrate transport module to the first location in the processing chamber and transferring the substrate to the substrate transport module. A backside of the substrate makes contact with a plurality of proximity pins extending to a predetermined height above a substrate cooling surface of the substrate transport module. The method also includes providing a vacuum force to the backside of the substrate. The vacuum force is applied through a plurality of vacuum ports, each of the plurality of vacuum ports being disposed in one of the plurality of proximity pins. The method further includes transferring thermal energy from the substrate to the substrate cooling surface through a process of conduction from the substrate cooling surface to a plurality of coolant channels disposed in the substrate transport module and moving the substrate transport module to the second location in the processing chamber.

According to a particular embodiment of the present invention, an integrated thermal unit for processing substrates is provided. The integrated thermal unit includes a bake plate configured to heat a substrate supported on a surface of the bake plate and a chill plate configured to cool a substrate supported on a surface of the chill plate. The integrated thermal unit also includes a substrate transfer shuttle configured to transfer substrates from the bake plate to the chill plate. The substrate transfer shuttle has a temperature controlled substrate holding surface that is capable of cooling a substrate heated by the bake plate. The substrate transfer shuttle also has a plurality of proximity pins extending to a predetermined height above the temperature controlled substrate holding surface. Each of the plurality of proximity pins comprises an integrated vacuum port. In an exemplary embodiment, each of the plurality of proximity pins includes an annular upper portion having a support face positioned at the predetermined height, an annular lower portion mounted in the substrate transfer shuttle, and an internal orifice passing through the annular upper portion and the annular lower portion, thereby providing a fluid communication path from the support face to at least one of a plurality of vacuum channels disposed in the substrate transfer shuttle.

Many benefits are achieved by way of the present invention over conventional techniques. For example, embodiments of the present invention reduce the number of generated particles in comparison with conventional transfer shuttles, in which the contact area between the shuttle and wafer is maximized. Additionally, vacuum chucking of the substrate utilizing proximity pins with integrated vacuum ports provides precision flattening of the substrate to result in a uniform substrate to cooling surface gap as a function of substrate position. Depending upon the embodiment, one or more of these benefits, as well as other benefits, may be achieved. These and other benefits will be described in more detail throughout the present specification and more particularly below in conjunction with the following drawings.

### BRIEF DESCRIPTION OF THE DRAWINGS

FIG. 1 is a plan view of an embodiment of a track lithography tool in which the embodiments of the present invention may be used;

FIG. 2 is a simplified conceptual view of one embodiment of an integrated thermal unit according to the present invention;

FIG. 3A is a simplified perspective view of an integrated thermal unit as depicted in FIG. 2;

FIG. 3B is a simplified perspective view of an integrated thermal unit as depicted in FIG. 2 with some elements removed;

FIG. 4 is a simplified block diagram that illustrates a sequence of events that is performed by a thermal unit to thermally treat wafers according to one embodiment of the present invention;

FIG. 5 is a simplified cross-sectional view of a portion of an integrated thermal unit according to an embodiment of the present invention;

FIG. 6 is a simplified perspective view of an actively chilled transfer shuttle according to an embodiment of the present invention;

FIG. 7A is a simplified cross-sectional illustration of a portion of an actively chilled transfer shuttle according to an embodiment of the present invention;

FIG. 7B is a simplified schematic diagram of a proximity pin with integrated vacuum port according to an embodiment of the present invention;

FIG. 8 is a conceptual view of an alternative embodiment of an integrated thermal unit according to the present invention;

FIG. 9 is a plot of temperature versus time produced using a thermal model of a shuttle according to an embodiment of the present invention; and

FIGS. 10A and 10B are plots of temperature versus time produced using a conventional shuttle and an actively chilled transfer shuttle according to an embodiment of the present invention, respectively.

### DETAILED DESCRIPTION OF SPECIFIC EMBODIMENTS

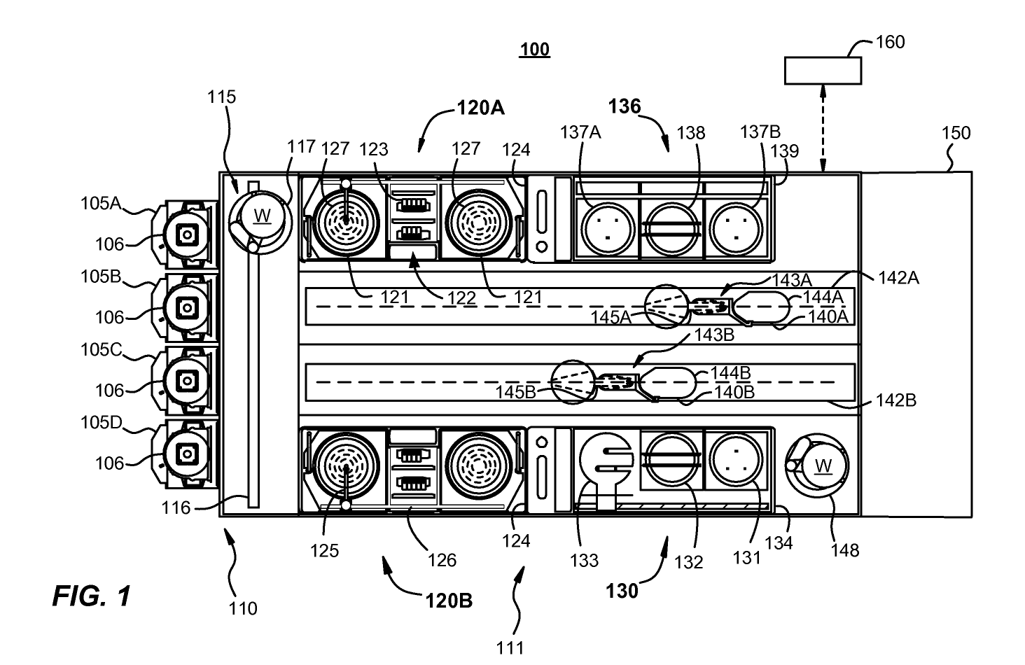

FIG. 1 is a plan view of an embodiment of a track lithography tool in which the embodiments of the present invention may be used. As illustrated in FIG. 1, the track lithography tool contains a front end module 110 (sometimes referred to as a factory interface) and a process module 111. In other embodiments, the track lithography tool includes a rear module (not shown), which is sometimes referred to as a scanner interface. Front end module 110 generally contains one or more pod assemblies or FOUPS (e.g., items 105A-D) and a front end robot assembly 115 including a horizontal motion assembly 116 and a front end robot 117. The front end module 110 may also include front end processing racks (not shown). The one or more pod assemblies 105A-D are generally adapted to accept one or more cassettes 106 that may contain one or more substrates or wafers that are to be processed in the track lithography tool. The front end module 110 may also contain one or more pass-through positions (not shown) to link the front end module 110 and the process module 111.

Process module 111 generally contains a number of processing racks 120A, 120B, 130, and 136. As illustrated in FIG. 1, processing racks 120A and 120B each include a coater/developer module with shared dispense 124. A coater/developer module with shared dispense 124 includes two coat bowls 121 positioned on opposing sides of a shared dispense bank 122, which contains a number of dispense nozzles 123 providing processing fluids (e.g., bottom anti-reflection coating (BARC) liquid, resist, developer, and the like) to a wafer mounted on a substrate support 127 located in the coat bowl 121. In the embodiment illustrated in FIG. 1, a nozzle positioning member 125 sliding along a track 126 is able to pick up a dispense nozzle 123 from the shared dispense bank 122 and position the selected dispense nozzle over the wafer for dispense operations. Coat bowls with dedicated dispense banks are provided in alternative embodiments.

Processing rack 130 includes an integrated thermal unit 134 including a bake plate 131, a chill plate 132 and a shuttle 133. The bake plate 131 and the chill plate 132 are utilized in heat treatment operations including post exposure bake (PEB), post-resist bake, and the like. In some embodiments the shuttle 133, which moves wafers in the x-direction between the bake plate 131 and the chill plate 132, is chilled to provide for initial cooling of a wafer after removal from the bake plate 131 and prior to placement on the chill plate 132. Moreover, in other embodiments shuttle 133 is adapted to move in the z-direction, enabling the use of bake and chill plates at different z-heights. Processing rack 136 includes an integrated bake and chill unit 139, with two bake plates 137A and 137B served by a single chill plate 138.

One or more robot assemblies (robots) 140 are adapted to access the front-end module 110, the various processing modules or chambers retained in the processing racks 120A, 120B, 130, and 136, and the scanner 150. By transferring substrates between these various components, a desired processing sequence can be performed on the substrates. The two robots 140 illustrated in FIG. 1 are configured in a parallel processing configuration and travel in the x-direction along horizontal motion assembly 142. Utilizing a mast structure (not shown), the robots 140 are also adapted to move orthogonal to the transfer direction. Utilizing one or more of three directional motion capabilities, robots 140 are able to place wafers in and transfer wafers between the various processing chambers retained in the processing racks that are aligned along the transfer direction.

Referring to FIG. 1, the first robot assembly 140A and the second robot assembly 140B are adapted to transfer substrates to the various processing chambers contained in the processing racks 120A, 120B, 130, and 136. In one embodiment, to perform the process of transferring substrates in the track lithography tool, robot assembly 140A and robot assembly 140B are similarly configured and include at least one horizontal motion assembly 142, a vertical motion assembly 144, and a robot hardware assembly 143 supporting a robot blade 145. Robot assemblies 140 are in communication with a controller 160 that controls the system. In the embodiment illustrated in FIG. 1, a rear robot assembly 148 is also provided.

The scanner 150 is a lithographic projection apparatus used, for example, in the manufacture of integrated circuits. The scanner 150 exposes a photosensitive material that was deposited on the substrate in the cluster tool to some form of radiation to generate a circuit pattern corresponding to an individual layer of the integrated circuit device to be formed on the substrate surface.

Each of the processing racks 120A, 120B, 130, and 136 contain multiple processing modules in a vertically stacked arrangement. That is, each of the processing racks may contain multiple stacked coater/developer modules with shared dispense 124, multiple stacked integrated thermal units 134, multiple stacked integrated bake and chill units 139, or other modules that are adapted to perform the various processing steps required of a track photolithography tool. As examples, coater/developer modules with shared dispense 124 may be used to deposit a bottom antireflective coating (BARC) and/or deposit and/or develop photoresist layers. Integrated thermal units 134 and integrated bake and chill units 139 may perform bake and chill operations associated with hardening BARC and/or photoresist layers after application or exposure.

In one embodiment, controller 160 is used to control all of the components and processes performed in the cluster tool. The controller 160 is generally adapted to communicate with the scanner 150, monitor and control aspects of the processes performed in the cluster tool, and is adapted to control all aspects of the complete substrate processing sequence. The controller 160, which is typically a microprocessor-based controller, is configured to receive inputs from a user and/or various sensors in one of the processing chambers and appropriately control the processing chamber components in accordance with the various inputs and software instructions retained in the controller's memory. The controller 160 generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller 160 determines which tasks are performable in the processing chambers. Preferably, the program is software readable by the controller 160 and includes instructions to monitor and control the process based on defined rules and input data.

It is to be understood that embodiments of the invention are not limited to use with a track lithography tool such as that depicted in FIG. 1, but may be used in any track lithography tool including the many different tool configurations described in U.S. patent application Ser. No. 11/112,281 entitled “Cluster Tool Architecture for Processing a Substrate” filed on Apr. 22, 2005, and Ser. No. 11/315,984 entitled “Cartesian Robot Cluster Tool Architecture” filed on Dec. 22, 2005, both of which are hereby incorporated by reference for all purposes. In addition, embodiments of the invention may be used in other semiconductor processing equipment.

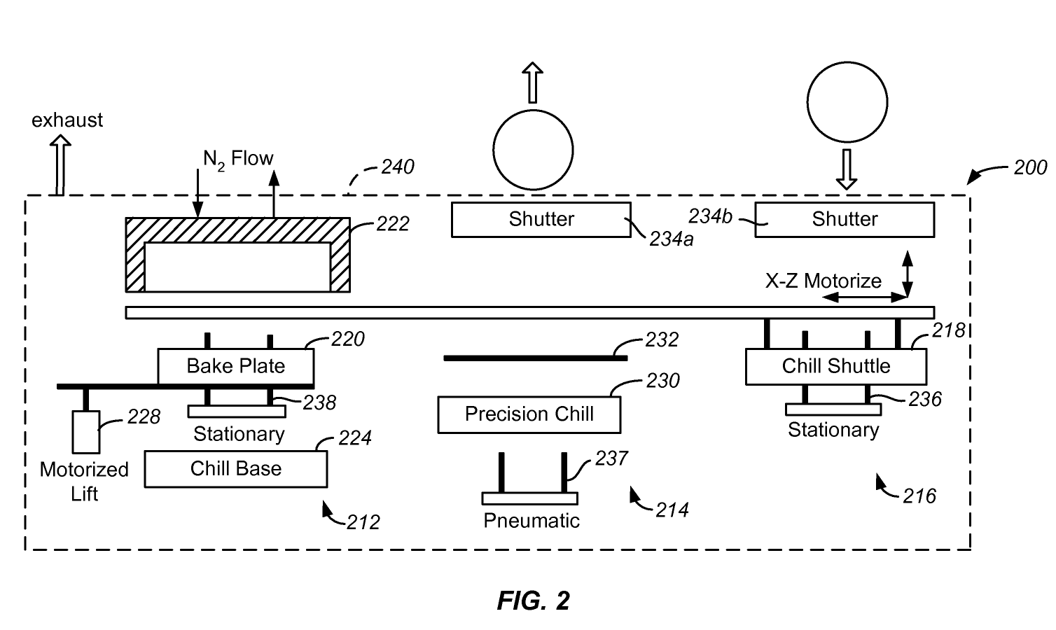

FIG. 2 is a simplified conceptual view of one embodiment of an integrated thermal unit 200 according to the present invention. Integrated thermal unit 200 includes a bake station 212, a chill station 214 and a shuttle station 216 all within an enclosed housing 240. Chill station 216 includes a shuttle 218 for transferring substrates between the bake and chill stations as needed. Bake station 212 includes a bake plate 220, an enclosure 222 and a chill base 224. Bake plate 220 is moveable between a wafer loading position (shown in FIG. 2), a closed heating position in which the bake plate is urged towards and within clam shell enclosure 222 by a motorized lift 228 and a cooling position in which the bake plate contacts chill base 224. Chill base 224 is engageably coupled to bake plate chill to enable the set point temperature of the bake plate to be rapidly changed from a relatively high, bake temperature to a lower bake temperature when, for example, switching to a new thermal recipe.

Chill station 214 includes a chill plate 230 and a particle shield 232 that protects a wafer situated on chill plate 230 from possible particle contamination when shuttle 218 passes over the chill station to transfer a wafer to or from bake station 212. Substrates can be transferred into and out of thermal unit 210 through elongated openings that are operatively coupled to shutters 234a and 234b, respectively.

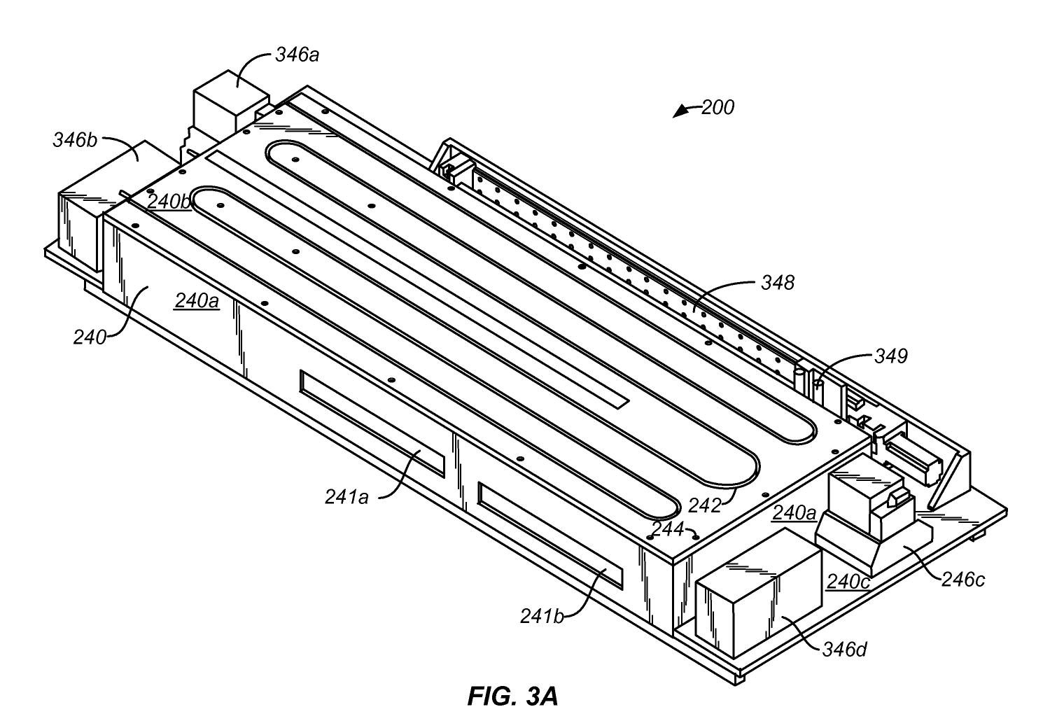

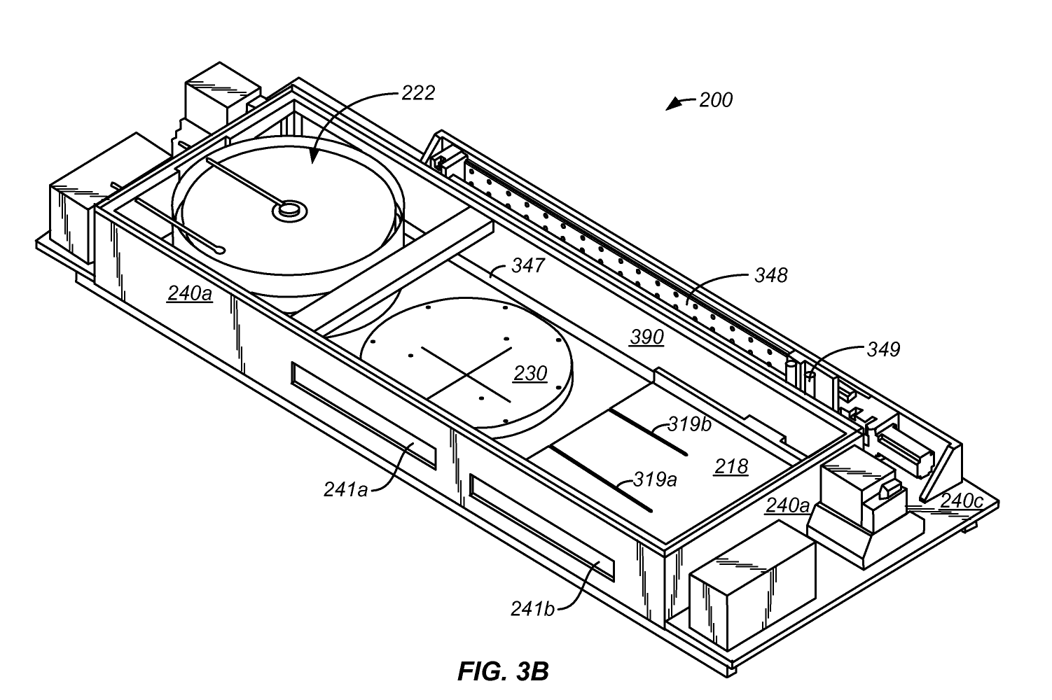

As shown in FIG. 3A, which is a simplified perspective view of integrated thermal unit 200 depicted in FIG. 2, thermal unit 200 includes an exterior housing 240 made of aluminum or another suitable material. Housing 240 is long relative to its height in order to allow bake station 212, chill station 214 and shuttle station 216 to be laterally adjacent to each other and to allow multiple integrated thermal units to be stacked on top of each other in a track lithography tool as described below with respect to FIG. 1. In one particular embodiment, housing 240 is just 20 centimeters high.

Housing 240 includes side pieces 240a, a top piece 240b and a bottom piece 240c. Front side piece 240a includes two elongated openings 241a, 241b that allow substrates to be transferred into and out of the thermal unit. Opening 241a is operatively coupled to be closed and sealed by shutter 234a (not shown) and opening 241b is operatively coupled to be closed and sealed by shutter 234b (also not shown). Top piece 240b of housing 240 includes coolant channels 242 that allow a coolant fluid to be circulated through the channels in order to control the temperature of top piece 240b when an appropriate plate (not shown) is attached to top piece 240b via screw holes 244. Similar coolant channels are formed in the lower surface of bottom piece 240c.

Also shown in FIG. 3A is various control circuitry 346a-346d which controls the precision baking operation of bake station 212 and the precision cooling operation of chill station 214. Tracks 348 and 349 enable shuttle 218 (not visible within FIG. 3A) to move linearly along the length of the thermal unit and vertically within the thermal unit as discussed in more detail below. In one embodiment, control circuitry 346a-346b is positioned near stations 212 and 214 (e.g., within three feet) in order to enable more accurate and responsive control of temperature adjusting mechanisms associated with each station.

FIG. 3B is a simplified perspective view of integrated thermal unit 200 as seen with top piece 240b and particle shield 232 (shown in FIG. 2) removed. In FIG. 3B, shuttle 218, chill plate 230 and clam shell enclosure 222 of bake station 212 are visible. Also visible is a space 347 between rear support piece 390 of housing 240 and bottom piece 240c. Space 347 extends along much of the length of integrated thermal unit 200 to allow shuttle 218 to transfer wafers between stations 212, 214, and 216 as discussed in detail below.

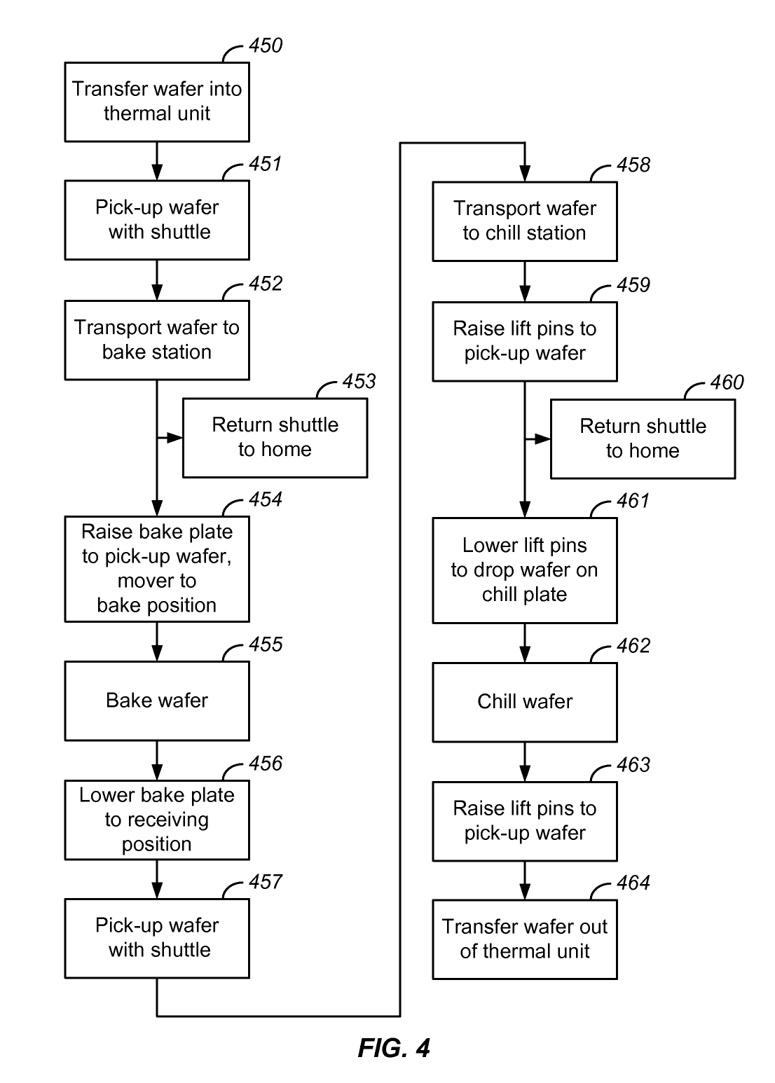

In order to better appreciate and understand the general operation of integrated thermal unit 200, reference is now made to FIG. 4 along with FIGS. 2 and 3B. FIG. 4 is a simplified block diagram that illustrates a sequence of events that is performed by thermal unit 200 to thermally treat wafers according to one embodiment of the present invention. A wafer may be treated in accordance with the process set forth in FIG. 4 after, for example, having a photoresist layer deposited over the wafer at an appropriate coating station of a track lithography tool. While the discussion below focuses on treating a single wafer within unit 200, a person of skill in the art will appreciate that thermal unit 200 will often be used to simultaneously process two wafers. For example, while one wafer is being heated on bake plate 220, thermal unit 200 can be in the process of cooling another wafer on chill plate 230 or transferring another wafer out of the thermal unit at the completion of its thermal treatment.

As shown in FIG. 4, a wafer's history in thermal unit 200 starts by transferring the wafer into the thermal unit 200 through wafer transfer slot 241b and placing the wafer onto stationary lift pins 236 (FIG. 2) at shuttle station 216 (FIG. 4, step 450). The wafer may be transferred into thermal unit 200 by, for example, a central robot that services both wafer transfer slots 241a and 241b as well as one or more coating or developing stations in a track lithography tool (not shown). Typically wafer transfer slot 241b is closed by shutter 234b, thus step 450 also includes moving shutter 234b to open slot 241b. During step 450 shuttle 218 is in a wafer receiving position at station 216 where lift pins 236 extend through slots 319a and 319b of the shuttle 218. After the wafer is properly positioned on lift pins 236, the robot arm recedes out of the thermal unit and chill shuttle 218 is raised to lift the wafer off of stationary lift pins 236 (FIG. 4, step 451) and then moved linearly along the length of the thermal unit to transfer the wafer to bake station 212 (FIG. 4, step 452). The path to bake station 212 takes shuttle 218 over particle shield 232 at chill station 214.

At bake station 212, the wafer is placed on lift pins 238 and shuttle 218 is free to handle another task or return to its home position at shuttle station 216 (FIG. 4, step 453). While the shuttle is being returned to home position, bake plate 220 is raised by motorized lift 228, thereby picking the wafer up off of stationary lift pins 238 and bringing the wafer into its bake position within clam shell enclosure 222 (FIG. 4, step 454). Once inside claim shell enclosure 222 the wafer is heated or baked according to a desired thermal recipe (FIG. 4, step 455).

After completion of bake step 455, the bake plate 220 is lowered to its wafer receiving position, dropping the wafer off on lift pins 238 (FIG. 4, step 456). Next, shuttle 218 returns to bake station 212 and picks the wafer up off of lift pins 238 (FIG. 4, step 457) and brings the wafer to chill station 214 (FIG. 4, step 458). The path to chill station 214 takes shuttle 218 over particle shield 232 to shuttle station 216 where shuttle 218 is lowered and then moved towards chill station 214. Once at chill station 214, lift pins 237 are raised by a pneumatic lift to lift the wafer off of the shuttle (FIG. 4, step 459). Shuttle 218 is then free to handle another task or return to its home position at station 216 (FIG. 4, step 460) and lift pins 237 are lowered to drop the wafer of onto chill plate 230 (FIG. 4, step 461).

The wafer is then cooled on chill plate 230 according to a predetermined thermal recipe (FIG. 4, step 462). After completion of the cooling process, lift pins 237 are raised to pick the wafer up off of the chill plate (FIG. 4, step 463) and the wafer is transferred out of the integrated thermal unit through elongated slot 241a (FIG. 4, step 464) by, for example, being picked up by the same central robot that transferred the wafer into the thermal unit in step 450. Typically, elongated slot 241a is closed by shutter 234a, thus step 464 also includes opening shutter 234a to open slot 241a.

Embodiments of the invention allow a process such as that described above to be carried out in a highly controllable and highly repeatable manner. Thus, embodiments of the invention help ensure an extremely high degree of uniformity in the thermal treatment of each wafer that is processed within integrated thermal unit 200 according to a particular thermal recipe. As discussed in more detail below, a number of specific aspects of the present invention can be used independent from each other or in combination to help achieve such a repeatable, uniform wafer history.

One such aspect is the placement of bake plate 220 with respect to chill plate 230. Specifically, in some embodiments of the invention bake plate 220 is positioned within integrated thermal unit 200 at a position that is higher than the position of chill plate 230. Because heat generated from bake plate 220 generally rises to an upper portion of thermal unit 200, such positioning helps minimize thermal cross-talk between the bake station and chill station that may otherwise lead to discrepancies in the thermal treatment of wafers over time.

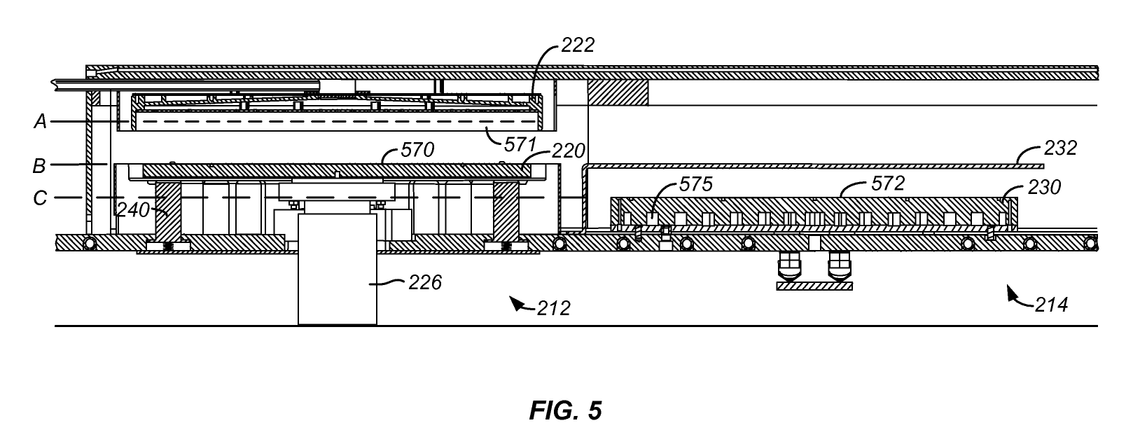

This aspect of the invention is illustrated in FIG. 5, which is a simplified cross-sectional view of a portion of integrated thermal unit 200 showing bake plate 220 and chill plate 230. As shown in FIG. 5, when bake plate 220 is within clam shell enclosure 222 at a baking position 571, wafer support surface 570 lies in a horizontal plane A that is well above the horizontal plane C that wafer support surface 572 of chill plate 230 lies in. In some embodiments plane A is at least 4 cm above plane C and in one particular embodiment plane A is 6 cm above plane C. The chill plate 230 includes a number of cooling channels 575 adapted to support the flow of a cooling fluid (e.g., deionized water) through the chill plate. The layout of the various cooling channels 575 is structured to provide uniform cooling as a function of plate position, suitable thermal transfer rates, and the like. One of ordinary skill in the art would recognize many variations, modifications, and alternatives.

Maintaining such a height difference in the positions of bake plate 220 and chill plate 230 helps minimize thermal cross-talk between the two stations and helps ensure a highly controlled, repeatable thermal treatment among multiple wafers.

The thermal unit 200 including the actively chilled transfer shuttle (shuttle 218) provides a number of advantages including: a) eliminates two pick and place moves that would be performed by a shared robot if the bake plate and chill plate were not locally integrated; b) the shuttle acts as a heat shield between the substrate and bake plate during entry; c) the actively chilled transfer shuttle rapidly cools the heated wafer below typical chemically amplified resist activation temperatures; and d) enables the processing of two wafers simultaneously.

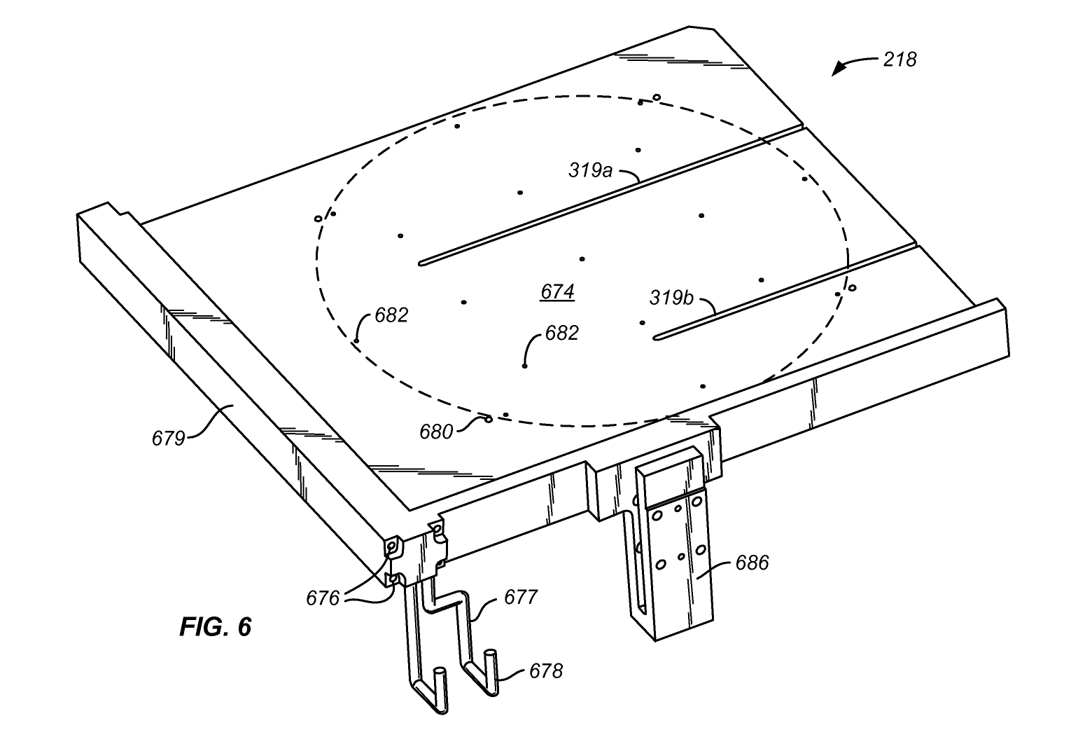

Another aspect of the present invention that helps ensure an extremely high degree of uniformity in the thermal treatment of each wafer is the design of shuttle 218. As shown in FIG. 6, which is a simplified perspective view of shuttle 218, the shuttle includes a wafer receiving area 674 upon which a semiconductor wafer is placed while the shuttle is transferring the wafer from one station to another. The shuttle 218 is referred to herein as an actively chilled transfer shuttle, an actively chilled transport module, and other similar terms. Such terms are not intended to limit embodiments of the present invention, but to merely provide alternative phrases to more completely describe these embodiments. In one embodiment, shuttle 218 is made from aluminum and wafer receiving area 674 and other portions of an upper surface 675 of the shuttle are actively cooled by a coolant (e.g., deionized water) that flows through coolant passages (not shown) in the shuttle. In an embodiment, the coolant passages or channels are machined in a roughed out part and a cover is vacuum brazed to create the enclosed channels.

The coolant is delivered to the coolant passages by tubes that connect to inlets/outlets 676, which in turn connect to a manifold (not shown) within portion 679 of shuttle 218 that helps distribute the fluid evenly throughout the shuttle. The fluid tubes are at least partially supported by fingers 678 of tube support mechanism 677 as shuttle 218 traverses the length of the integrated thermal unit. In contrast with designs in which cooling channels are limited to long circular flow patterns, embodiments described herein include straight flow patterns that are in a counter-flow arrangement throughout the shuttle. In addition, in some designs, the path length for each counter-flow channel is approximately the same. This arrangement provides better temperature uniformity than a passively chilled plate.

Actively cooling wafer receiving surface 674 helps maintain precise thermal control of wafer temperature during all times while the wafer is within thermal unit 200. Actively cooling shuttle 218 also starts the wafer cooling process sooner than it would otherwise be initiated if such active cooling did not occur until the wafer is transferred to a dedicated chill station, which in turn reduces the overall thermal budget of the wafer.

In an embodiment, the shuttle is fabricated of 6061-T6 aluminum with a TUFRAM™ coating. TUFRAM™ is a General Magnaplate proprietary coating. The coating is essentially an anodized coating impregnated with a “Teflon-like” material. A benefit provided by this coating is the ease of cleaning, which results from the reduced friction. Another benefit is the increased wear resistance as compared to a hard anodized coating. Generally, the transfer shuttle is fabricated from a thermally conductive material, for example, metal. In a particular embodiment, the transfer shuttle has a thickness of about 10 mm and is fabricated from aluminum, which has a high thermal capacity. In other embodiments, other suitable materials with appropriate thicknesses are utilized as will be evident to one of skill in the art.

Also shown in FIG. 6 are slots 319a, 319b, wafer pocket buttons 680 and small contact area proximity pins 682. Slots 319a, 319b allow the shuttle to be positioned or moved under a wafer being held by lift pins. For example, in chill station 214 a wafer is held above the chill plate prior to and after chill step 462 (see FIG. 4) on a set of three lift pins arranged in a triangular formation. Slot 319a is aligned to allow shuttle 218 to slide past two of the three lift pins and slot 319b is aligned to allow the shuttle to slide pass the third lift pin. Pocket buttons 680 screw into threaded holes in the upper surface of shuttle 218 and extend above the surface to help center a wafer within wafer receiving area 674. Pocket buttons 680, which may be tapered, can be made from any appropriately soft material, such as a thermoplastic material, that exhibits strong fatigue resistance and thermal stability. In one embodiment, buttons 680 are made from polyetheretherketone, which is also known as PEEK.

Proximity pins 682 are distributed across upper surface 674 of shuttle 218 and are fabricated from a material with a low coefficient of friction, such as sapphire or other suitable materials. Proximity pins 682 allow the wafer being transported by shuttle 218 to be brought into very close proximity of temperature controlled surface 674. In an embodiment, the proximity pins provide a proximity gap of 100±10 μm, although this particular range is not required. In an embodiment, the proximity gap is created by 17 2 mm diameter sapphire balls. The balls are crimped in place and height controlled by special CNC tooling. In alternative embodiments, other features are utilized to create the proximity gap while allowing for vacuum chucking. For example, both sapphire balls and centering features are replaced in one design with alumina cylinders. One of ordinary skill in the art would recognize many variations, modifications, and alternatives.

The small space between the wafer and temperature controlled surface 674 helps create uniform cooling across the entire surface area of the wafer while at the same time minimizing contact between the underside of the wafer and the shuttle to reduce the likelihood that particles or contaminants may be generated from such contact. As will be evident to one of skill in the art, the presence of particles has detrimental effects on other downstream processes. Further details of proximity pins 682 are set forth in U.S. application Ser. No. 11/111,155, entitled “Purged Vacuum Chuck with Proximity Pins,” and filed on Apr. 20, 2005, which is hereby incorporated by reference for all purposes. In one particular embodiment, shuttle 218 includes four pocket buttons 680 and 17 proximity pins 682. Another embodiment utilizes 16 proximity pins. One of ordinary skill in the art would recognize many variations, modifications, and alternatives.

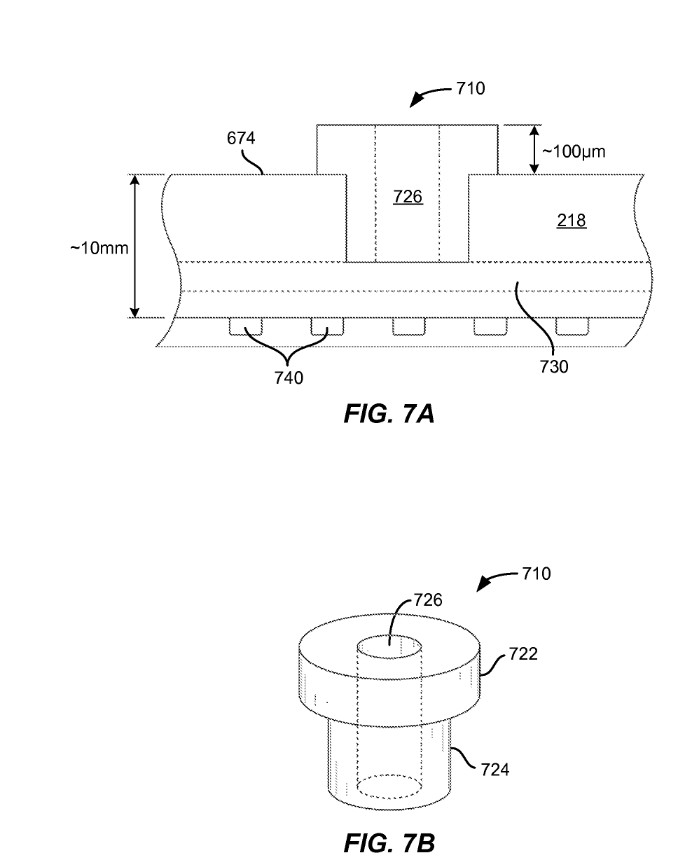

FIG. 7A is a simplified cross-sectional illustration of a portion of an actively chilled transfer shuttle according to an embodiment of the present invention. As illustrated in FIG. 7A, the actively chilled transfer shuttle includes transfer surface 674 and proximity pins 710. The proximity pins 710 illustrated in FIG. 7A include an integrated vacuum port. Although the proximity pins 710 have features differing from those provided by proximity pins 682, it will be appreciated that various proximity pin designs may be used in the shuttle as appropriate to the particular application.

In the embodiment illustrated in FIG. 7A, the proximity pins 710 include an integrated vacuum port 726 as described more fully with reference to FIG. 7B. The actively chilled transfer shuttle has one or more integrated vacuum ducts 730, which are connected to a suitable vacuum port (not shown), which is connected to a vacuum source. Thus, vacuum pressure is provided to each proximity pin 710 distributed across the transfer surface 674. Generally, fabrication of the shuttle includes drilling of mounting holes from the transfer surface to the previously provided integrated vacuum ducts. The proximity pins are subsequently inserted in the mounting holes and fixed in place. One of ordinary skill in the art would recognize many variations, modifications, and alternatives.

In addition to vacuum ducts 730, the actively chilled transfer shuttle includes a number of coolant passages 740 that support the flow of a coolant (e.g., deionized water). Operating a manner similar to the cooling channels 575 illustrated in FIG. 5, the coolant passages in the actively chilled transfer shuttle provide for heat transfer from the transfer surface 674, through the body of the shuttle, and to the coolant flowing through the coolant passages. Thus, in the embodiment illustrated in FIG. 7A, the transfer shuttle 218 includes both vacuum ducts 730 and coolant passages 740 to provide vacuum to the substrate and cooling to the shuttle, respectively. Although the vacuum ducts 730 and coolant passage 740 are illustrated as running perpendicular to each other in FIG. 7A, this drawing is merely illustrative, as actual designs may utilize other geometries. One of ordinary skill in the art would recognize many variations, modifications, and alternatives.

In an embodiment, the proximity pins extend to a predetermined height above the transfer surface 674 of the shuttle. In a particular embodiment, the predetermined height is about 100 μm. In other embodiments, the predetermined height varies as appropriate to the particular application. In some embodiments, the process used to mount the proximity pins in the shuttle includes a height adjustment process. During transport operations, vacuum at each proximity pin is utilized to flatten the substrate. The use of proximity pins with integrated vacuum ports enables a uniform separation between the substrate and the transfer surface 674, thereby increasing the thermal uniformity of the heat transfer process. Additionally, the rate of thermal transfer between the substrate and the shuttle is increased by reductions in proximity pin height, thereby decreasing the time the substrate spends transitioning to a final temperature and increasing system throughput. Additionally, increased thermal coupling between the substrate and the plate assembly reduces the thermal impact of any chamber non-uniformities.

In an embodiment, the proximity pins are fabricated from a material with a low coefficient of friction. Accordingly, contact between the proximity pins and the substrate will produce a reduced number of particles. In contrast with some conventional transfer shuttles, in which the contact between the shuttle and wafer (i.e., the area of the backside of the wafer in physical contact with the shuttle surface) is maximized, the use of proximity pins minimizes the contact area on the backside of the substrate. Although the rate of heat transfer through an air gap is not as high as achieved by placing all or a significant portion of the backside of the substrate in physical contact with the transfer surface, the reduction in the number of generated particles provides desirable benefits. Thus, in contrast with some conventional transfer shuttles in which the substrate is held or clamped directly to the transfer shuttle by vacuum or electrostatic force, resulting in maximization of the substrate/shuttle contact area, embodiments of the present invention reduce the contact area through the use of proximity pins.

In embodiments of the present invention, a number of proximity pins are distributed across the transfer surface of the shuttle. For example, in one particular embodiment, 17 proximity pins are utilized with the following locations: one pin at the center, four pins arranged at corners of a square concentric with the center pin, with a side equal to 50 mm, and 12 pins arranged near the periphery of the plate assembly, separated from each other by arcs of 30°.

FIG. 7B is a simplified schematic diagram of a proximity pin with integrated vacuum port according to an embodiment of the present invention. Generally, substrates or wafers possess a degree of bowing or warpage before they are placed on the transfer shuttle. Thus, embodiments of the present invention use methods and systems to reduce the wafer bow by flattening the wafer. As illustrated in FIG. 7B, proximity pin 710 includes a central through hole 726, which passes through the upper portion 722 and the lower portion 724 of the proximity pin. As shown in FIG. 7A, the through hole 726 is in fluid communication with a vacuum duct 730, thereby providing a vacuum source to the upper surface of the proximity pin. Utilizing a vacuum source, the wafer is flattened during the cooling process.

In another design, the proximity pins are fabricated using hollow cylindrical elements that are characterized by low thermal conductivity and high abrasion resistance. In this particular design, instead of having an upper portion 722 with a diameter greater than the lower portion 724, the proximity pin is cylindrical. During fabrication, the proximity pins are inserted into pre-formed mounting holes and are ground or polished to provide a predetermined and uniform proximity gap. As previously described, the proximity pins are in fluid communication with vacuum duct 730 to provide vacuum chucking for the substrate.

The substrate transport module may include additional vacuum ports or orifices (not shown) fabricated in the substrate cooling surface and in fluid communication with the vacuum duct 730. Thus, some embodiments of the present invention supplement the vacuum provided through the proximity pins with integrated vacuum ports with additional vacuum ports in the transfer surface of the shuttle. Separate valving may be applied to the integrated vacuum ports and the vacuum orifices to provide controllable vacuum as appropriate to the particular application. Vacuum chuck systems are described more fully in U.S. Patent Application Publication No. 2006/0130767, entitled “Purged Vacuum Chuck with Proximity Pins,” filed Apr. 20, 2005, commonly assigned, and incorporated by reference in its entirety for all purposes. Moreover, alternative embodiments supplement or replace the vacuum attraction with other techniques, including electrostatic attraction. Electrostatic chucks are described more fully in U.S. Patent Application Publication No. 2006/0238954, entitled “Electrostatic Chuck for Track Thermal Plates,” filed on Jun. 15, 2005, and incorporated by reference in its entirety for all purposes. One of ordinary skill in the art would recognize many variations, modifications, and alternatives.

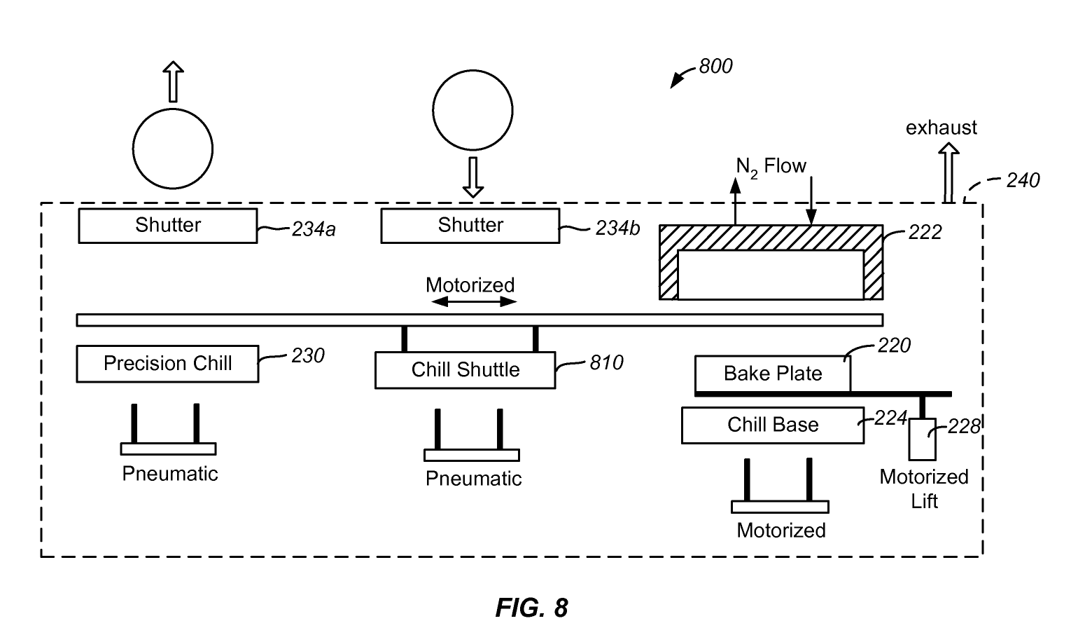

FIG. 8 is a conceptual view of an alternative embodiment of an integrated thermal unit 800 according to the present invention. One primary difference between the embodiment of the invention shown in FIG. 8 and the embodiment shown in FIG. 2 is the placement of the bake, chill, and shuttle stations 212, 214, and 216, respectively. In FIG. 8, the shuttle (shuttle 810 as compared to shuttle 218) has been moved to a central position between the bake station and chill station. Such an arrangement provides a benefit in further reducing thermal cross-talk between the bake and chill stations and also alleviates the need for particle shield 232 to be positioned over chill plate 230 because shuttle 810 does not need to “fly over” the chill plate to deliver a wafer to bake plate 220. One benefit of the arrangement of FIG. 2 as compared to that of FIG. 8 is the separation of shuttle 218 from bake plate 220 when the shuttle is in a position to receive wafers passed into the integrated thermal unit.

Also, shuttle 810 in FIG. 8 is operatively configured to move linearly along a X-axis (horizontal path) along the length of housing 240 but is not configured to be moveable vertically. This difference utilizes moveable lift pins at each of the bake, chill and shuttle stations in order to properly exchange wafers between shuttle 810 and the station.

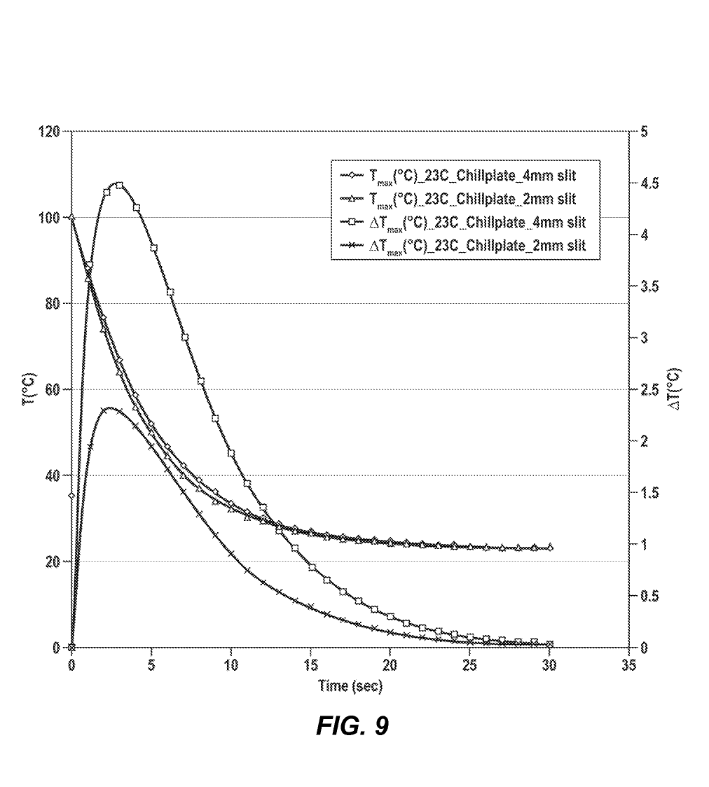

In order to quantify some of the benefits provided by embodiments described throughout the present specification, thermal modeling and experimental studies were performed. FIG. 9 is a plot of temperature versus time produced using a thermal model of a shuttle according to an embodiment of the present invention. In this finite element analysis (FEA), the thermal performance of the shuttle was modeled. Thermal parameters investigated were the temporal temperature values for the substrate and spatial temperature distributions for the substrate. In a particular analysis, cooling of the substrate to a temperature less than a threshold temperature, reduction of the thermal imprint of the shuttle slits below a predetermined threshold, and reduction of the substrate spatial non-uniformities below a predetermined value were examined. In a particular application, a transient within-wafer (WIW) uniformity less than 5° C. during the substrate temperature ramp down was set as a performance target.

FIG. 9 plots the theoretical maximum temperature and temperature change (ΔT) for a substrate cooled from 100° C. to 23° C. on a chilled transport shuttle according to an embodiment of the present invention. For purposes of comparison, data is provided for shuttles with a 2 mm and a 4 mm slit width. The model shows that for a 4 mm slit width, the WIW temperature uniformity during the transient cool down is ˜4.5° C. For a 2 mm slit width, the WIW temperature uniformity during the transient cool down is ˜2.5° C. For both 4 mm and 2 mm slit width designs, the maximum temperature of the substrate drops from 100° C. to 23° C. in approximately 30 seconds. Thus, embodiments of the present invention provide chilled transport modules for improved control over the overall PEB cycle during the initial ramp down. Without limiting the present invention, the inventors believe that for some chemically activated resists, the temperature uniformity during the initial period of cooling is a critical factor to overall CD uniformity.

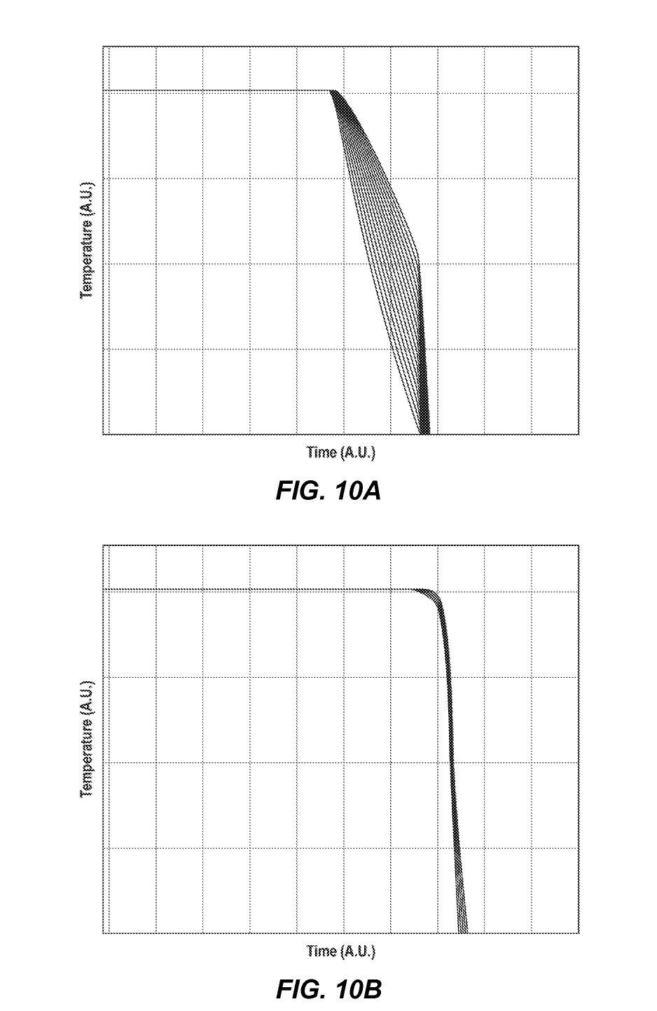

FIGS. 10A and 10B are plots of temperature versus time produced using a conventional shuttle and an actively chilled transfer shuttle according to an embodiment of the present invention, respectively. For purposes of comparison, a conventional track lithography tool was tested, in which a central robot picks up the wafer from the bake plate and transfers it to a chill plate. In this conventional design, a hot wafer is contacted by a robot blade with discrete contact locations and transported in ambient air to a chill plate that is located in a separate module of the tool. As illustrated in FIG. 10A, a series of wafers processed using this conventional tool will exhibit a WIW transient temperature uniformity spread during this transfer.

Utilizing an actively chilled wafer transfer shuttle provided according to an embodiment of the present invention, the WIW transient temperature uniformity spread shown in FIG. 10A is significantly reduced. Our measurements demonstrated that the chilled transport shuttle performance during the transient cool down is <±3° C., which is marked improvement in comparison to the convention process. As illustrated in FIG. 10B, not only does the actively chilled transport shuttle cool the wafer during the bake to chill transfer more uniformly, but the cool down ramp rate is also increased.

While the present invention has been described with respect to particular embodiments and specific examples thereof, it should be understood that other embodiments may fall within the spirit and scope of the invention. The scope of the invention should, therefore, be determined with reference to the appended claims along with their full scope of equivalents.

What is claimed is:

1. A substrate transport module adapted to transport a substrate in a processing chamber of a semiconductor processing apparatus, the substrate transport module comprising:
a substrate cooling surface;
a plurality of coolant channels disposed in the substrate transport module and in thermal communication with the substrate cooling surface;
a plurality of vacuum channels disposed in the substrate transport module; and
a plurality of proximity pins extending to a predetermined height above the substrate cooling surface, wherein each of the plurality of proximity pins is in fluid communication with one or more of the plurality of vacuum channels.

2. The substrate transport module of claim 1 wherein each of the plurality of proximity pins comprise an integrated vacuum port.

3. The substrate transport module of claim 2 wherein the predetermined height is about 100 μm.

4. The substrate transport module of claim 3 wherein the predetermined height is less than 100 μm.

5. The substrate transport module of claim 1 further comprising a plurality of vacuum orifices disposed in the substrate cooling surface, wherein the plurality of vacuum orifices are in fluid communication with one or more of the plurality of vacuum channels.

6. The substrate transport module of claim 1 further comprising an electrostatic member adapted to provide an electrostatic attraction force at the substrate cooling surface.

7. The substrate transport module of claim 1 wherein each of the plurality of proximity pins comprise:
an annular upper portion having a support face positioned at the predetermined height;
an annular lower portion mounted in the substrate transport module; and
an internal orifice passing through the annular upper portion and the annular lower portion, thereby providing a fluid communication path from at least one of the plurality of vacuum channels and the support face.

8. The substrate transport module of claim 7 wherein a diameter of the annular upper portion is greater than a diameter of the annular lower portion.

9. The substrate transport module of claim 1 wherein each of the plurality of proximity pins comprise an alumina structure.

10. The substrate transport module of claim 9 wherein the alumina structure comprises an alumina cylinder.

11. The substrate transport module of claim 1 further comprising a plurality of buttons arranged around a periphery of the substrate cooling surface, the plurality of buttons being configured to secure the substrate within the substrate cooling surface.

12. The substrate transport module of claim 1 wherein the processing chamber comprises an integrated thermal unit.

13. The method of claim 12 wherein the semiconductor processing apparatus comprises a track lithography tool.

14. A method of transporting a substrate from a first location in a processing chamber of a semiconductor processing apparatus to a second location in the processing chamber, the method comprising:
moving a substrate transport module to the first location in the processing chamber;
transferring the substrate to the substrate transport module, wherein a backside of the substrate makes contact with a plurality of proximity pins extending to a predetermined height above a substrate cooling surface of the substrate transport module;
providing a vacuum force to the backside of the substrate, wherein the vacuum force is applied through a plurality of vacuum ports, each of the plurality of vacuum ports being disposed in one of the plurality of proximity pins;
transferring thermal energy from the substrate to the substrate cooling surface through a process of conduction from the substrate cooling surface to a plurality of coolant channels disposed in the substrate transport module; and
moving the substrate transport module to the second location in the processing chamber.

15. The method of claim 14 wherein providing the vacuum force to the backside of the substrate causes a flattening of the substrate.

16. The method of claim 14 further comprising transferring thermal energy from the substrate to the substrate cooling surface through a process of convection.

17. The method of claim 14 further comprising securing the substrate within the substrate receiving surface using a plurality of buttons arranged around a periphery of the substrate receiving surface.

18. An integrated thermal unit for processing substrates, the integrated thermal unit comprising:
a bake plate configured to heat a substrate supported on a surface of the bake plate;
a chill plate configured to cool a substrate supported on a surface of the chill plate; and
a substrate transfer shuttle configured to transfer substrates from the bake plate to the chill plate, the substrate transfer shuttle having:
a temperature controlled substrate holding surface that is capable of cooling a substrate heated by the bake plate; and
a plurality of proximity pins extending to a predetermined height above the temperature controlled substrate holding surface, wherein each of the plurality of proximity pins comprises an integrated vacuum port.

19. The integrated thermal unit of claim 18 wherein each of the plurality of proximity pins comprises:
an annular upper portion having a support face positioned at the predetermined height;
an annular lower portion mounted in the substrate transfer shuttle; and
an internal orifice passing through the annular upper portion and the annular lower portion, thereby providing a fluid communication path from the support face to at least one of a plurality of vacuum channels disposed in the substrate transfer shuttle.

20. The integrated thermal unit of claim 18 further comprising a shuttle station at which substrates can be transferred into the thermal unit and picked up by the substrate transfer shuttle.

21. The integrated thermal unit of claim 20 further comprising a housing within which the bake plate, chill plate and shuttle station are enclosed.

22. The integrated thermal unit of claim 21 wherein the bake plate, chill plate and shuttle station are arranged linearly along a length of the housing.

23. The integrated thermal unit of claim 22 further comprising a particle shield positioned over the chill plate and wherein the substrate transfer shuttle travels between the shuttle station, the chill plate and the bake plate within the housing along a linear path above the particle shield.

24. The integrated thermal unit of claim 21 wherein the substrate transfer shuttle is configured to travel from one end to an opposite end of the length of the housing along a linear path.

25. The integrated thermal unit of claim 18 wherein the substrate transfer shuttle comprises a plurality of coolant channels underneath the temperature controlled substrate holding surface.

26. The integrated thermal unit of claim 18 wherein the substrate transfer shuttle further comprises a plurality of buttons arranged around a periphery of a substrate receiving area portion of the temperature controlled substrate holding surface, the plurality of buttons configured to secure a substrate within the substrate receiving area portion of the temperature controlled substrate holding surface.
